(19) United States
(12) Patent Application Publication
(10) Pub. No.: US 2023/0263035 A1
(43) Pub. Date: Aug. 17, 2023

(54) WINDOW AND DISPLAY DEVICE INCLUDING THE SAME

(71) Applicant: SAMSUNG DISPLAY CO., LTD., Yongin-si (KR)

(72) Inventors: Seongsik CHOI, Yongin-si (KR); Jonghwan CHO, Yongin-si (KR)

(21) Appl. No.: 18/105,870

(22) Filed: Feb. 5, 2023

(30) Foreign Application Priority Data
Feb. 17, 2022 (KR) 10-2022-0021039

(51) Int. Cl. H10K 59/80; H10K 59/122; H10K 59/38; H10K 59/40

(52) U.S. Cl. CPC H10K 59/8791; H10K 59/122; H10K 59/38; H10K 59/40; H10K 59/872; H10K 59/873; H10K 59/8792

(57) ABSTRACT

A window includes a window substrate, a first layer disposed on the window substrate, a second layer disposed on the first layer, a third layer disposed on the second layer, and an anti-fingerprint layer disposed on the third layer. The first layer has a refractive index in a range of about 1.2 to about 1.4, the second layer includes chromium oxide (Cr₂O₃), the third layer has a refractive index in a range of about 1.4 to about 1.6, and the anti-fingerprint layer includes perfluoropolyether (PFPE).

This application claims priority to Korean Patent Application No. 10-2022-0021039, filed on Feb. 17, 2022, and all the benefits accruing therefrom under 35 U.S.C. § 119, the content of which in its entirety is herein incorporated by reference.

### BACKGROUND

### 1. Field

One or more embodiments relate to a window and a display device including the window, and more particularly, to a window having a reduced reflectance and a display device including the window.

### 2. Description of the Related Art

Recently, display devices have been widely used in various fields. In addition, as the display devices are becoming thinner and lighter, the range of use of the display devices is further increasing.

As display devices are used in various ways, there are various methods of designing the shapes of the display devices. In addition, functions that may be associated or linked to a display device are increasing.

### SUMMARY

According to embodiments of the disclosure, deterioration in visibility of a display device due to reflection of external light may be effectively prevented or substantially minimized.

According to one or more embodiments, a window includes a window substrate, a first layer disposed on the window substrate, where the first layer has a refractive index in a range of about 1.2 to about 1.4, a second layer disposed on the first layer, where the second layer includes chromium oxide (Cr₂O₃), a third layer disposed on the second layer, where the third layer has a refractive index in a range of about 1.4 to about 1.6, and an anti-fingerprint layer disposed on the third layer, where the anti-fingerprint layer includes perfluoropolyether (PFPE).

In an embodiment, the second layer may have a refractive index which is greater than a refractive index of the first layer and a refractive index of the third layer.

In an embodiment, the second layer may have a refractive index in a range of about 1.6 to about 2.0.

In an embodiment, the first layer may have a thickness in a range of about 50 nanometers (nm) to about 150 nm, the second layer may have a thickness in a range of about 5 nm to about 15 nm, and the third layer may have a thickness in a range of about 5 nm of about 15 nm.

In an embodiment, the first layer may include magnesium fluoride (MgF₂), and the third layer may include silicon oxide (SiO₂).

In an embodiment, the second layer may include chromium oxide (Cr₂O₃) covalently bonded to silicon (Si).

In an embodiment, a contact angle of a surface of the window with respect to water may be about 95° or more after applying a load of 1 kg to the surface of the window by using an eraser and then reciprocating by a distance of 15 mm at a speed of 40 cycles/min for 6000 times.

According to one or more embodiments, a window includes a window substrate, a first layer disposed on the window substrate, where the first layer has a refractive index in a range of about 1.2 to about 1.4, a second layer disposed on the first layer, where the second layer has a refractive index in a range of about 1.6 to about 2.0, a third layer disposed on the second layer, where the third layer has a refractive index in a range of about 1.4 to about 1.6, and an anti-fingerprint layer disposed on the third layer, where the anti-fingerprint layer includes perfluoropolyether (PFPE), where a contact angle of a surface of the window with respect to water is about 95° or more after applying a load of 1 kg to the surface of the window by using an eraser and then reciprocating by a distance of 15 mm at a speed of 40 cycles/min for 6000 times.

In an embodiment, the first layer may have a thickness in a range of about 50 nm to about 150 nm, the second layer may have a thickness in a range of about 5 nm to about 15 nm, and the third layer may have a thickness in a range of about 5 nm of about 15 nm.

In an embodiment, the first layer may include magnesium fluoride (MgF₂), the second layer may include chromium oxide (Cr₂O₃), and the third layer may include silicon oxide (SiO₂).

In an embodiment, the second layer may include chromium oxide (Cr₂O₃) covalently bonded to silicon (Si).

According to one or more embodiments, a display device includes a substrate, a light-emitting element disposed on the substrate, where the light-emitting element includes a first electrode, a second electrode, and an intermediate layer between the first electrode and the second electrode, a filter layer disposed on the light-emitting element, where the filter layer includes a color filter layer and a light-blocking layer, and a window disposed on the filter layer. In such embodiments, the window includes a window substrate, a first layer disposed on the window substrate, where the first layer has a refractive index in a range of about 1.2 to about 1.4, a second layer disposed on the first layer, where the second layer includes chromium oxide (Cr₂O₃), a third layer disposed on the second layer, where the third layer has a refractive index in a range of about 1.4 to about 1.6, and an anti-fingerprint layer disposed on the third layer, where the anti-fingerprint layer includes perfluoropolyether (PFPE).

In an embodiment, the second layer may have a refractive index which is greater than a refractive index of the first layer and a refractive index of the third layer.

In an embodiment, the second layer may have a refractive index in a range of about 1.6 to about 2.0.

In an embodiment, the first layer may have a thickness in a range of about 50 nm to about 150 nm, the second layer may have a thickness in a range of about 5 nm to about 15 nm, and the third layer may have a thickness in a range of about 5 nm of about 15 nm.

In an embodiment, the first layer may include magnesium fluoride (MgF₂), and the third layer may include silicon oxide (SiO₂).

In an embodiment, the second layer may include chromium oxide (Cr₂O₃) covalently bonded to silicon (Si).

In an embodiment, a contact angle of a surface of the window with respect to water may be about 95° or more after applying a load of 1 kg to the surface of the window by using an eraser and then reciprocating by a distance of 15 mm at a speed of 40 cycles/min for 6000 times.

In an embodiment, the display device may further include a pixel defining layer in which a first opening is defined to expose at least a portion of the first electrode.

In an embodiment, the light-blocking layer may define a second opening overlapping the first opening.

In an embodiment, at least a portion of the color filter layer may be in the second opening.

In an embodiment, the color filter layer may at least partially overlap the intermediate layer.

In an embodiment, the filter layer may further include an overcoat layer disposed on the color filter layer.

In an embodiment, the display device may further include an encapsulation layer between the light-emitting element and the filter layer, and an input sensing layer between the encapsulation layer and the filter layer.

### BRIEF DESCRIPTION OF THE DRAWINGS

The above and other features of certain embodiments of the disclosure will be more apparent from the following description taken in conjunction with the accompanying drawings, in which:

FIG. 1 is a schematic plan view of a display device according to an embodiment;

FIG. 2 is schematic cross-sectional view of a display device according to an embodiment;

FIG. 3 is a schematic plan view of a display device according to an embodiment;

FIG. 4 is an equivalent circuit diagram of a pixel in a display device according to an embodiment;

FIG. 5 is a schematic cross-sectional view of a display device according to an embodiment;

FIG. 6 is a schematic cross-sectional view of a window in a display device according to an embodiment;

FIG. 7 is a graph illustrating a wear-resistance evaluation result of an embodiment;

FIG. 8 is a graph illustrating a wear-resistance evaluation result of an embodiment;

FIG. 9 is a graph illustrating a wear-resistance evaluation result of Comparative Example 1;

FIG. 10 is a graph illustrating a wear-resistance evaluation result of Comparative Example 1;

FIG. 11 is a graph illustrating a wear-resistance evaluation result of Comparative Example 2;

FIG. 12 is a graph illustrating a wear-resistance evaluation result of Comparative Example 2; and

FIG. 13 is a graph illustrating reflectance measurement results according to wavelengths of an embodiment and a window substrate.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. Throughout the disclosure, the expression “at least one of a, b or c” or “at least one selected from a, b and c” indicates only a, only b, only c, both a and b, both a and c, both b and c, all of a, b, and c, or variations thereof.

As the present disclosure allows for various changes and numerous embodiments, particular embodiments will be illustrated in the drawings and described in detail in the written description. Effects and features of the present disclosure and methods of achieving the same will be apparent with reference to embodiments and drawings described below in detail. This disclosure may, however, be embodied in many different forms and should not be construed as being limited to the exemplary embodiments set forth herein.

In the following embodiments, while such terms as “first,” “second,” etc., may be used to describe various elements, such elements must not be limited to the above terms.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that when a layer, region, or component is referred to as being formed on another layer, region, or component, it can be directly or indirectly formed on the other layer, region, or component. That is, for example, intervening layers, regions, or components may be present.

Sizes of components in the drawings may be exaggerated for convenience of explanation. For example, since sizes and thicknesses of components in the drawings are arbitrarily illustrated for convenience of explanation, the following embodiments are not limited thereto.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

In the following embodiment, it will be understood that when a wire is referred to as “extending in a first direction or a second direction,” it cannot only extend in a linear shape, but also can extend in the first direction or the second direction in a zigzag or curved line.

In the following embodiment, a “plan view” indicates that a portion of a target object is seen from above, and a “cross-sectional view” indicates that a portion of a target object is vertically cut and the cross-section is viewed from the side. In the following embodiment, a term “overlapping” includes overlapping in a plan view and a cross-sectional view.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described in detail with reference to the accompanying drawings.

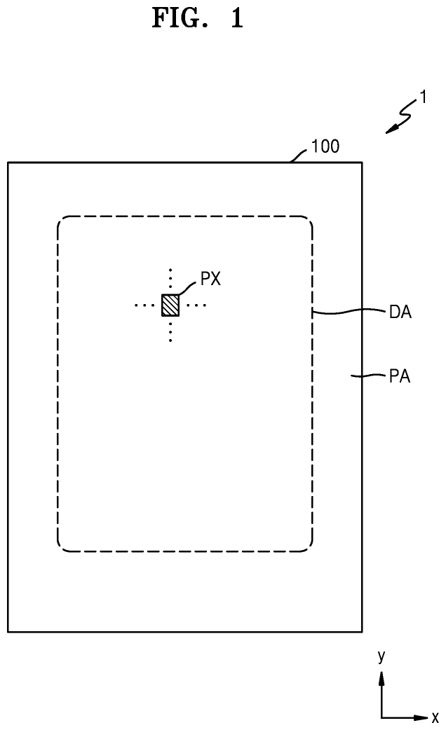

FIG. 1 is a schematic plan view of a display device 1 according to an embodiment.

Referring to FIG. 1, an embodiment of the display device 1 may include a display area DA displaying an image and a peripheral area PA around the display area DA. The display device 1 may provide an image to the outside by using light emitted from the display area DA. In an embodiment, the display device 1 includes a substrate 100, and the display area DA and the peripheral area PA may be defined on the substrate 100.

The substrate 100 may include various materials, such as glass, metal, plastic, or the like. In an embodiment, the substrate 100 may include a flexible material. Here, the flexible material refers to a material which may be twisted, bent, folded, or rolled. The substrate 100 of the flexible material may include ultra-thin glass, metal, or plastic.

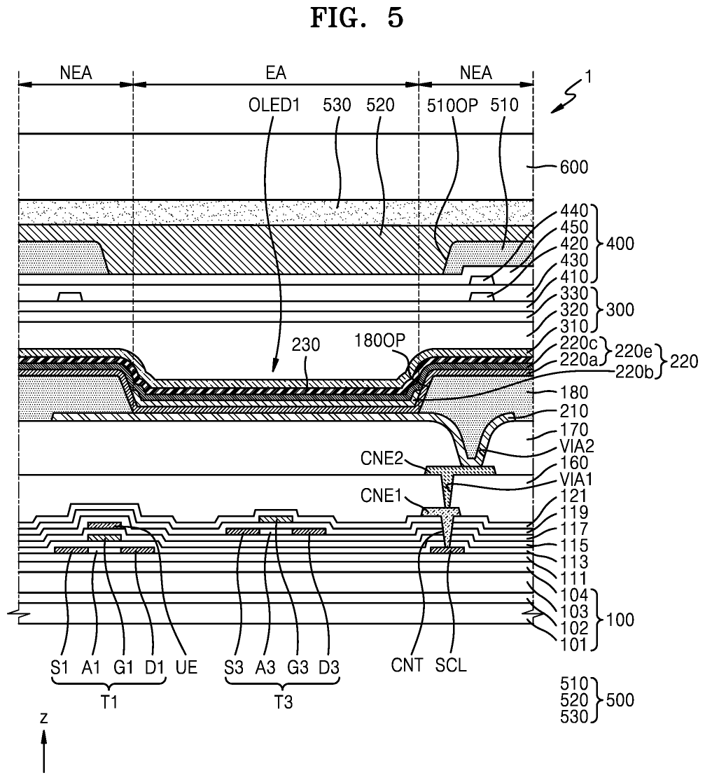

A pixel PX including a light-emitting element, such as an organic light-emitting diode, may be arranged in the display area DA of the substrate 100. A plurality of pixels PX may be included in the display area DA o, and the plurality of pixels PX may be arranged in various forms, such as a stripe arrangement, a pentile arrangement, a mosaic arrangement, or the like, to implement an image. Hereinafter, for convenience of description, embodiment where the display device 1 includes a light-emitting element OLED (refer to FIG. 5), and the light-emitting element OLED is an organic light-emitting diode will be described, but the disclosure is not limited thereto. In an alternative embodiment, for example, the light-emitting element may also be an inorganic light-emitting diode or a quantum dot light-emitting diode.

Although FIG. 1 illustrates an embodiment where the planar shape of the display area DA is a rectangular shape, the disclosure is not limited thereto. In an alternative embodiment, for example, the display area DA may include a polygonal shape, such as a triangular shape, a pentagonal shape, a hexagonal shape, or the like, or a circular shape, an elliptical shape, an atypical shape, or the like.

The peripheral area PA of the substrate 100 is an area around the display area DA, and may be an area where no image is displayed. Various lines configured to deliver electrical signals to the display area DA, as well as pads to which a printed circuit board or a driver integrated circuit (IC) chip is attached, may be in the peripheral area PA.

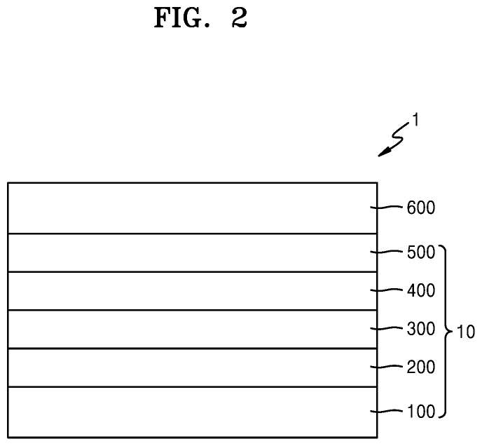

FIG. 2 is schematic cross-sectional view of the display device 1 according to an embodiment.

Referring to FIG. 2, an embodiment of the display device 1 may include a display panel 10 and a window 600 on the display panel 10. The display panel 10 may include a substrate 100, a display layer 200, an encapsulation layer 300, an input sensing layer 400, and a filter layer 500, which are sequentially stacked one on another. In such an embodiment, the display device 1 includes the display panel 10, such that the display device 1 includes the substrate 100, the display layer 200, the encapsulation layer 300, the input sensing layer 400, and the filter layer 500, which are sequentially stacked one on another.

The substrate 100 may include a glass material, a ceramic material, a metal material, or a flexible or bendable material. In an embodiment where the substrate 100 includes a flexible or bendable material, the substrate 100 may include a polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate.

The substrate 100 may have a single-layered structure or a multi-layered structure, and may further include an inorganic layer in a case of a multi-layered structure. In some embodiments, the substrate 100 may have a structure of organic material/inorganic material/organic material/inorganic material. This will be described below in greater detail with reference to FIG. 5.

The display layer 200 may be disposed on the substrate 100. The display layer 200 may include a thin-film transistor, a light-emitting element, insulating layers, and organic insulating layers. The encapsulation layer 300 may be disposed on the display layer 200.

The encapsulation layer 300 may include a thin-film encapsulation layer including at least one inorganic film and at least one organic film, or an encapsulation substrate including a glass material. In an embodiment where the encapsulation layer 300 includes a glass material, a sealant including frit or the like may be between the substrate 100 and the encapsulation layer 300, and the sealant may be in the peripheral area PA (refer to FIG. 1). The sealant in the peripheral area PA may prevent and minimize penetration of moisture through a side surface of the display device 1 while surrounding the display area DA.

The input sensing layer 400 may be disposed on the encapsulation layer 300. The input sensing layer 400 may obtain coordinate information according to an external input, for example, a touch event. The input sensing layer 400 may be separately formed on a touch substrate and then adhered to the encapsulation layer 300 through an adhesive layer, such as an optically clear adhesive (OCA). In an embodiment, the input sensing layer 400 may be directly formed on the encapsulation layer 300. In such an embodiment, an adhesive layer may not be between the input sensing layer 400 and the encapsulation layer 300.

In an embodiment, the filter layer 500 may be disposed on the input sensing layer 400. The filter layer 500 may include a light-blocking layer 510 (refer to FIG. 5), a color filter layer 520 (refer to FIG. 5), and an overcoat layer 530 (refer to FIG. 5), as to be described below with reference to FIG. 5. This will be described below in greater detail with reference to FIG. 5.

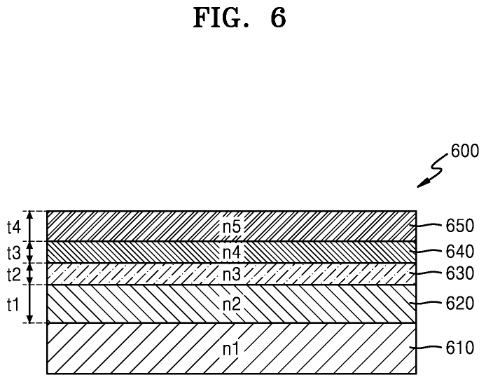

In an embodiment, the window 600 may be disposed on the filter layer 500. The window 600 may include a window substrate 610 (refer to FIG. 6), a first layer 620 (refer to FIG. 6), a second layer 630 (refer to FIG. 6), a third layer 640 (refer to FIG. 6), and an anti-fingerprint layer 650 (refer to FIG. 6), as to be described below with reference to FIG. 6. This will be described below in greater detail with reference to FIG. 6.

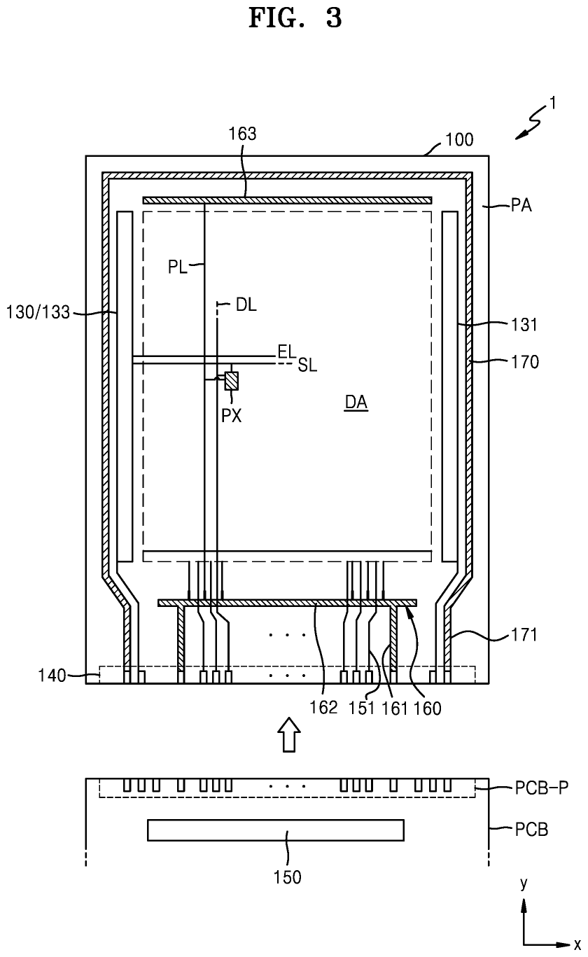

FIG. 3 is a schematic plan view of the display device 1 according to an embodiment.

Referring to FIG. 3, an embodiment of the display device 1 may include the display area DA and the peripheral area PA, and include a plurality of pixels PX in the display area DA. Each of the plurality of pixels PX may include a light-emitting element OLED. In an embodiment, the light-emitting element OLED may be an organic light-emitting diode. Each pixel PX may emit, for example, red, green, blue, or white light through the light-emitting element OLED. Hereinafter, each pixel PX may mean a sub-pixel that emits a different color from another, and each pixel PX may include, for example, one of a red sub-pixel, a green sub-pixel, and a blue sub-pixel. The display area DA may be covered by the encapsulation layer 300 (refer to FIG. 2) to be protected from external air or moisture.

Each pixel PX may be electrically connected to outer circuits in the peripheral area PA. A first scan driving circuit 130, a second scan driving circuit 131, an emission control driving circuit 133, a terminal 140, a data driving circuit 150, a first power supply line 160, and a second power supply line 170 may be in the peripheral area PA.

The first scan driving circuit 130 and the second scan driving circuit 131 may provide scan signals to each pixel PX through a scan line SL. The second scan driving circuit 131 may be arranged in parallel with the first scan driving circuit 130 with the display area DA therebetween. Some of the plurality of pixels PX in the display area DA may be electrically connected to the first scan driving circuit 130, and the remaining pixels PX may be connected to the second scan driving circuit 131. In an alternative embodiment, the second scan driving circuit 131 may be omitted. The emission control driving circuit 133 may provide an emission control signal to each pixel PX through an emission control line EL.

The terminal 140 may be arranged on one side of the substrate 100. The terminal 140 may not be covered by an insulating layer but exposed to be electrically connected to a printed circuit board PCB. A terminal PCB-P of the printed circuit board PCB may be electrically connected to the terminal 140 of the display device 1. The printed circuit board PCB may transmit a signal or power of a controller (not shown) to the display device 1.

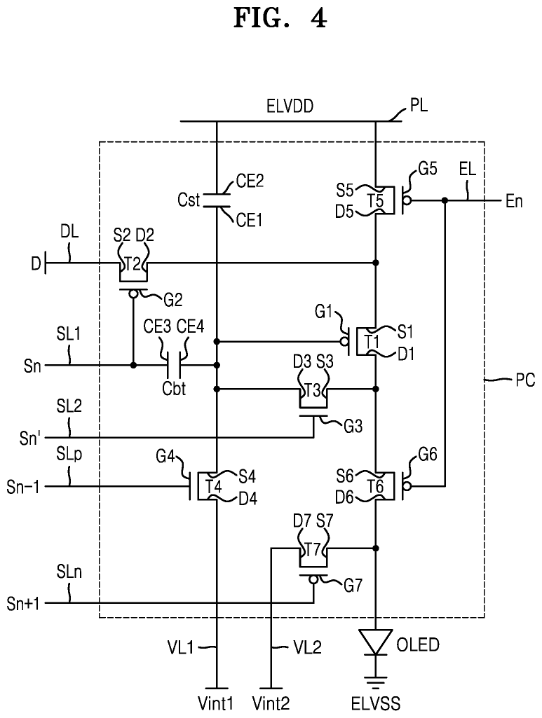

Control signals generated by the controller may be respectively transmitted to the first and second scan driving circuits 130 and 131 through the printed circuit board PCB. The controller may respectively provide first and second power supply voltages ELVDD and ELVSS (refer to FIG. 4) to the first and second power supply lines 160 and 170 through first and second connection lines 161 and 171. The first power supply voltage ELVDD may be provided to each pixel PX through a driving voltage line PL connected to the first power supply line 160, and the second power supply voltage ELVSS may be provided to a second electrode 230 (refer to FIG. 5) of each pixel PX connected to the second power supply line 170.

The data driving circuit 150 may be electrically connected to a data line DL. A data signal of the data driving circuit 150 may be provided to each pixel PX through a connection line 151 connected to the terminal 140 and the data line DL connected to the connection line 151. Although FIG. 3 shows an embodiment where the data driving circuit 150 is arranged in the printed circuit board PCB, the disclosure is not limited thereto. In an alternative embodiment, the data driving circuit 150 may be disposed on the substrate 100. In an embodiment, for example, the data driving circuit 150 may be arranged between the terminal 140 and the first power supply line 160.

The first power supply line 160 may include a first sub-line 162 and a second sub-line 163 both extending in parallel in a first direction (x direction) with the display area DA therebetween. The second power supply line 170 may partially surround the display area DA in a loop shape with one open side.

FIG. 4 is an equivalent circuit diagram of a pixel in a display device according to an embodiment.

Referring to FIG. 4, an embodiment of a pixel circuit PC may include a first transistor T1, a second transistor T2, a third transistor T3, a fourth transistor T4, a fifth transistor T5, a sixth transistor T6, a seventh transistor T7, a first storage capacitor Cst, and a second storage capacitor CT. In an embodiment, at least one selected from the first to seventh transistors T1 to T7 may be omitted.

The first to seventh transistors T1, T2, T3, T4, T5, T6, and T7, and the first and second storage capacitors Cst and Cbt may be connected to signal lines, a first initialization voltage line VL1, a second initialization voltage line VL2, and a driving voltage line PL. The signal lines may include a data line DL, a first scan line SL1, a second scan line SL2, a previous scan line SLp, a following scan line SLn, and an emission control line EL. In an embodiment, the signal lines, the first and second initialization voltage lines VL1 and VL2, and/or the driving voltage line PL may be shared by neighboring pixels.

The driving voltage line PL may be configured to deliver a first power supply voltage ELVDD to the first transistor T1. The first initialization voltage line VL1 may be configured to deliver a first initialization voltage Vint1 for initializing the first transistor T1 to the pixel circuit PC. The second initialization voltage line VL2 may be configured to deliver a second initialization voltage Vint2 for initializing the light-emitting element OLED to the pixel circuit PC.

Among the first to seventh transistors T1 to T7, the third transistor T3 and the fourth transistor T4 may be implemented as n-channel metal-oxide-semiconductor field-effect transistors (MOSFETs) (NMOSs), and the remaining transistors may be implemented as p-channel MOSFETs (PMOSs). However, the present disclosure is not limited thereto. In an embodiment, the third transistor T3, the fourth transistor T4, and the seventh transistor T7 may be implemented as NMOSs, and the remaining transistors may be implemented as PMOSs.

In this specification, “a transistor being electrically connected to a signal line or transistors being electrically connected to each other” means “the source, drain, and gate of the transistor have the same shape as the signal line or are connected through a connection electrode.”

The first transistor T1 may control the magnitude of a driving current flowing from the driving voltage line PL to the light-emitting element OLED based on a gate voltage of the first transistor T1. The first transistor T1 may include a gate G1 connected to a first lower electrode CE1 of the first storage capacitor Cst, and a source S1 connected to the driving voltage line PL through the fifth transistor T5. In addition, the first transistor T1 may include a drain D1 connected to the light-emitting element OLED through the sixth transistor T6.

The second transistor T2 may receive a data voltage D in response to a first scan signal Sn. The second transistor T2 may be configured to deliver the data voltage D to the source S1 of the first transistor T1, in response to the first scan signal Sn. The second transistor T2 may include a gate G2 connected to the first scan line SL1, a source S2 connected to the data line DL, and a drain D2 connected to the source S1 of the first transistor T1.

The first storage capacitor Cst may be connected between the driving voltage line PL and the first transistor T1. The first storage capacitor Cst may include a first upper electrode CE2 connected to the driving voltage line PL, and the first lower electrode CE1 connected to the gate G1 of the first transistor T1. The first storage capacitor Cst may store a difference between the first power supply voltage ELVDD applied to the driving voltage line PL and a gate voltage of the first transistor T1, and may maintain the gate voltage of the first transistor T1.

The third transistor T3 may be connected in series between the drain D1 and the gate G1 of the first transistor T1, and may connect the drain D1 and the gate G1 of the first transistor T1 to each other in response to a second scan signal Sn′. The third transistor T3 may include a gate G3 connected to the second scan line SL2, a source S3 connected to the drain D1 of the first transistor T1, and a drain D3 connected to the gate G1 of the first transistor T1. The third transistor T3 may include a plurality of transistors connected in series to each other and simultaneously controlled by the second scan signal Sn′. Alternatively, the third transistor T3 may be omitted.

When the third transistor T3 is turned on in response to the second scan signal Sn′, the drain D1 and the gate G1 of the first transistor T1 may be connected to each other to diode-connect the first transistor T1.

The fourth transistor T4 may apply the first initialization voltage Vint1 to the gate G1 of the first transistor T1 in response to a previous scan signal Sn−1. The fourth transistor T4 may include a gate G4 connected to the previous scan line SLp, a source S4 connected to the gate G1 of the first transistor T1, and a drain D4 connected to the first initialization voltage line VL1. The fourth transistor T4 may also include a plurality of transistors connected in series to each other and simultaneously controlled by the previous scan signal Sn−1. Alternatively, the fourth transistor T4 may be omitted.

The fifth transistor T5 may connect the driving voltage line PL and the source S1 of the first transistor T1 to each other in response to an emission control signal En. The fifth transistor T5 may include a gate G5 connected to the emission control line EL, a source S5 connected to the driving voltage line PL, and a drain D5 connected to the source S1 of the first transistor T1. Alternatively, the fifth transistor T5 may be omitted.

The sixth transistor T6 may connect the drain D1 of the first transistor T1 and a first electrode 210 (refer to FIG. 5) of the light-emitting element OLED to each other in response to the emission control signal En. The sixth transistor T6 may be configured to deliver a driving current output from the first transistor T1 to the first electrode 210 of the light-emitting element OLED. The sixth transistor T6 may include a gate G6 connected to the emission control line EL, a source S6 connected to the drain D1 of the first transistor T1, and a drain D6 connected to the first electrode 210 of the light-emitting element OLED. Alternatively, the sixth transistor T6 may be omitted.

The seventh transistor T7 may apply the second initialization voltage Vint2 to the first electrode 210 of the light-emitting element OLED, in response to a following scan signal Sn+1. The seventh transistor T7 may include a gate G7 connected to the following scan line SLn, a source S7 connected to the first electrode 210 of the light-emitting element OLED, and a drain D7 connected to the second initialization voltage line VL2. Alternatively, the seventh transistor T7 may be omitted.

The seventh transistor T7 may be connected to the following scan line SLn, as shown in FIG. 4. Alternatively, the seventh transistor T7 may be connected to the emission control line EL to be driven based on the emission control signal En. Alternatively, the seventh transistor T7 may be connected to the previous scan line SLp to be driven based on the previous scan signal Sn−1.

The positions of sources and drains of the first to seventh transistors T1 to T7 may be changed according the type (p-type or n-type) of a transistor.

The second storage capacitor Cbt may include a second lower electrode CE3 and a second upper electrode CE4. The second upper electrode CE4 of the second storage capacitor Cbt may be connected to the first lower electrode CE1 of the first storage capacitor Cst, and the second lower electrode CE3 of the second storage capacitor Cbt may receive the first scan signal Sn. The second storage capacitor Cbt may compensate for a voltage drop at a gate terminal of the first transistor T1 by increasing a voltage of the gate terminal of the first transistor T1 at a time point in which the supply of the first scan signal Sn is stopped. Alternatively, the second storage capacitor Cbt may be omitted.

Although FIG. 4 illustrates an embodiment where the pixel circuit PC includes seven transistors and two storage capacitors, the disclosure is not limited thereto. The pixel circuit PC may include at least one transistor and at least one storage capacitor. In an embodiment, for example, the pixel circuit PC may be provided in various ways, such as including two transistors and one storage capacitor, including three transistors and one storage capacitor, or including nine transistors and two storage capacitors.

FIG. 5 is a schematic cross-sectional view of the display device 1 according to an embodiment. In particular, FIG. 5 is a cross-sectional view of the display area DA (refer to FIG. 1) in the display device 1 according to an embodiment.

FIG. 5 only illustrates the first transistor T1 and the third transistor T3 among the first to seventh transistors T1 to T7 described with reference to FIG. 4. However, the first transistor T1 and the third transistor T3 of FIG. 5 are shown to explain that the pixel PX includes a first semiconductor pattern including a silicon semiconductor and a second semiconductor pattern including an oxide semiconductor. The positions of the first transistor T1 and the third transistor T3 are not limited to the positions shown in FIG. 5.

Referring to FIG. 5, the display device 1 may include the substrate 100, the light-emitting element OLED disposed on the substrate 100, and the filter layer 500 disposed on the light-emitting element OLED. In an embodiment, the light-emitting element OLED disposed on the substrate 100 may be an organic light-emitting diode.

The substrate 100 may have a structure in which a layer including an organic material and a layer including an inorganic material are alternately stacked. In an embodiment, for example, the substrate 100 may include a first base layer 101, a first barrier layer 102, a second base layer 103, and a second barrier layer 104, which are sequentially stacked one on another.

The first base layer 101 may include an organic material. In an embodiment, for example, the first base layer 101 may include any one of polyimide, polyethylene naphthalate, polyethylene terephthalate, polyarylate, polycarbonate, polyetherimide, and polyethersulfone.

The first barrier layer 102 may be disposed on the first base layer 101. The first barrier layer 102 may include an inorganic material. In an embodiment, for example, the first barrier layer 102 may include silicon oxide, silicon oxynitride, silicon nitride, amorphous silicon, or the like. In an embodiment, the first barrier layer 102 may include two layers including different materials from each other. In such an embodiment, the refractive indices of the two layers may be different from each other. In an embodiment, for example, the first barrier layer 102 may include two layers respectively including silicon oxynitride and silicon oxide having a refractive index that is less than that of silicon oxynitride. However, the disclosure is not limited thereto.

The second base layer 103 may be disposed on the first barrier layer 102. The second base layer 103 may include a same material as that of the first base layer 101. However, the disclosure is not limited thereto. Alternatively, the second base layer 103 may also include a different material from that of the first base layer 101.

The second barrier layer 104 may be disposed on the second base layer 103. The second barrier layer 104 may include an inorganic material. In an embodiment, for example, the second barrier layer 104 may include silicon oxide, silicon oxynitride, silicon nitride, or the like.

A buffer layer 111 may be disposed on the substrate 100. The buffer layer 111 may reduce or block penetration of foreign substances, moisture, or external air from a lower portion of the substrate 100. The buffer layer 111 may include an inorganic material, such as silicon oxide, silicon oxynitride, or silicon nitride, and may be a single layer or a multilayer, each layer therein including at least one selected from the materials described above.

A semiconductor pattern may be disposed on the buffer layer 111. Hereinafter, the semiconductor pattern directly disposed on the buffer layer 111 is defined as a first semiconductor pattern. The first semiconductor pattern may include a silicon semiconductor. The first semiconductor pattern may include polysilicon. However, the disclosure is not limited thereto. The first semiconductor pattern may also include amorphous silicon.

FIG. 5 only illustrates a portion of the first semiconductor pattern, and the first semiconductor pattern may also be arranged in another area of the pixel PX (refer to FIG. 4). The first semiconductor pattern may include a doped area and a non-doped area. The doped area may be an area doped with an N-type dopant or a P-type dopant. A P-type transistor may include a doped area obtained by doping with a P-type dopant.

The first transistor T1 may include a source S1, an active A1, and a drain D1. The source S1, the active A1, and the drain D1 of the first transistor T1 may form the first semiconductor pattern. The source S1 and the drain D1 of the first transistor T1 may be apart from each other with the active A1 of the first transistor T1 therebetween.

A connection signal line SCL may be further disposed on the buffer layer 111. The connection signal line SCL may be connected to the drain D6 of the sixth transistor T6 (refer to FIG. 4). Alternatively, the connection signal line SCL may be omitted.

A first insulating layer 113 may be disposed on the buffer layer 111. The first insulating layer 113 may cover the first semiconductor pattern. In an embodiment, the first insulating layer 113 may include an inorganic material, such as silicon oxide, silicon oxynitride, or silicon nitride, and may be a single layer or a multilayer, each layer therein including at least one selected from the materials described above.

A gate G1 of the first transistor T1 may be disposed on the first insulating layer 113. The gate G1 may be defined by a portion of a metal pattern. The gate G1 of the first transistor T1 may at least partially overlap the first semiconductor pattern therebelow. In an embodiment, for example, the gate G1 may overlap the active A1 therebelow. The gate G1 may include a low-resistance conductive material, such as molybdenum (Mo), aluminum (Al), copper (Cu), or titanium (T1), and may be a single layer or a multilayer, each layer therein including at least one selected from the materials described above.

A second insulating layer 115 may be disposed on the first insulating layer 113. The second insulating layer 115 may cover the gate G1 of the first transistor T1 disposed on the first insulating layer 113. The second insulating layer 115 may include an inorganic material, such as silicon oxide, silicon oxynitride, or silicon nitride, and may be a single layer or a multilayer, each layer therein including at least one selected from the materials described above.

An upper electrode UE may be disposed on the second insulating layer 115. The upper electrode UE may at least partially overlap the gate G1 of the first transistor T1 therebelow. The upper electrode UE may be a portion of a metal pattern or a portion of a doped semiconductor pattern. A portion of the gate G1 and the upper electrode UE overlapping the portion of the gate G1 may form the first storage capacitor Cst (refer to FIG. 4). Alternatively, the upper electrode UE may be omitted.

Although not separately illustrated in FIG. 5, the first lower electrode CE1 (refer to FIG. 4) and the second upper electrode CE2 (refer to FIG. 4) of the first storage capacitor Cst may respectively be formed through the same operations as forming the gate G1 and the upper electrode UE. The first lower electrode CE1 may be disposed on the first insulating layer 113, and the first lower electrode CE1 may be electrically connected to the gate G1. In an embodiment, for example, the first lower electrode CE1 may have a shape integral with the gate G1.

A third insulating layer 117 may be disposed on the second insulating layer 115. The third insulating layer 117 may cover the upper electrode UE disposed on the second insulating layer 115. The third insulating layer 117 may include an inorganic material, such as silicon oxide, silicon oxynitride, or silicon nitride, and may be a single layer or a multilayer, each layer therein including at least one selected from the materials described above. In an embodiment, the third insulating layer 117 may include a plurality of silicon oxide layers and silicon nitride layers, which are alternately stacked one on another.

Although not separately illustrated in FIG. 5, the sources S2, S5, S6, and S7 (refer to FIG. 4), the drains D2, D5, D6, and D7 (refer to FIG. 4), and the gates G2, G5, G6, and G7 (refer to FIG. 4) of the second, fifth, sixth, and seventh transistors T2, T5, T6, and T7 (refer to FIG. 4) may be formed through a same operations of forming the source S1, the drain D1, and the gate G1 of the first transistor T1, respectively.

A semiconductor pattern may be disposed on the third insulating layer 117. Hereinafter, the semiconductor pattern disposed directly on the third insulating layer 117 is defined as a second semiconductor pattern. The second semiconductor pattern may include an oxide semiconductor. The oxide semiconductor may include a crystalline or amorphous oxide semiconductor.

In an embodiment, for example, the oxide semiconductor may include at least one material selected from indium (In), gallium (Ga), tin (Sn), zirconium (Zr), vanadium (V), hafnium (Hf), cadmium (Cd), germanium (Ge), chromium (Cr), titanium (Ti), and zinc (Zn). Alternatively, the oxide semiconductor may include indium tin oxide (ITO), indium-gallium-zinc oxide (IGZO), zinc oxide (ZnO), indium-zinc oxide (IZnO), zinc-indium oxide (ZIO), indium oxide (InO), titanium oxide (TiO), indium-zinc-tin oxide (IZTO), zinc-tin oxide (ZTO), or the like.

The third transistor T3 may include a source S3, an active A3, and a drain D3. The source S3, the active A3, and the drain D3 of the third transistor T3 may form the second semiconductor pattern. The source S3 and the drain D3 of the third transistor T3 may include a metal reduced from a metal oxide semiconductor. The source S3 and the drain D3 of the third transistor T3 may each include a metal layer having a certain thickness from an upper surface of the second semiconductor pattern and including a reduced metal.

A fourth insulating layer 119 may be disposed on the third insulating layer 117. The fourth insulating layer 119 may cover the second semiconductor pattern disposed on the third insulating layer 117. In an embodiment, the fourth insulating layer 119 may include an inorganic material, such as silicon oxide, silicon oxynitride, or silicon nitride, and may be a single layer or a multilayer, each layer therein including at least one selected from the materials described above.

In an embodiment, the fourth insulating layer 119 may be patterned to correspond to the gate G3 of the third transistor T3 thereon. In an embodiment, the gate G3 and the fourth insulating layer 119 may have a same shape as each other in a plan view.

The gate G3 of the third transistor T3 may be disposed on the fourth insulating layer 119. The gate G3 may be a portion of a metal pattern. The gate G3 of the third transistor T3 may at least partially overlap the second semiconductor pattern therebelow. In an embodiment, for example, the gate G3 may overlap the active A3 therebelow. The gate G3 may include a low-resistance conductive material, such as Mo, Al, Cu, or T1, and may be a single layer or a multilayer, each layer therein including at least one selected from the materials described above.

A fifth insulating layer 121 may be disposed on the fourth insulating layer 119. The fifth insulating layer 121 may cover the gate G3 disposed on the fourth insulating layer 119. In an embodiment, the fifth insulating layer 121 may include an inorganic material, such as silicon oxide, silicon oxynitride, or silicon nitride, and may be a single layer or a multilayer, each layer therein including at least one selected from the materials described above. In an embodiment, the fifth insulating layer 121 may include a plurality of silicon oxide layers and silicon nitride layers, which are alternately stacked one on another.

Although not separately illustrated in FIG. 5, the source S4 (refer to FIG. 4), the drain D4 (refer to FIG. 4), and the gate G4 (refer to FIG. 4) of the fourth transistor T4 (refer to FIG. 4) may be respectively formed through a same operations of forming the source S3, the drain D3, and the gate G3 of the third transistor T3.

In an embodiment, as described above, the semiconductor patterns of the third transistor T3 and the fourth transistor T4 are disposed on the third insulating layer 117, but the disclosure is not limited thereto. In an embodiment, for example, the semiconductor patterns of the third transistor T3 and the fourth transistor T4 may be disposed on the buffer layer 111, and the semiconductor patterns of the third transistor T3 and the fourth transistor T4 may also include silicon semiconductors.

At least one organic insulating layer may be disposed on the fifth insulating layer 121. In an embodiment, a first organic insulating layer 123 and a second organic insulating layer 125 may be disposed on the fifth insulating layer 121. Each of the first organic insulating layer 123 and the second organic insulating layer 125 may include at least one selected from polyimide resin, acrylic resin, methacrylic resin, polyisoprene, vinyl resin, epoxy resin, urethane resin, cellulose resin, siloxane resin, a polyamide resin, and perylene resin.

In an embodiment, the first organic insulating layer 123 and the second organic insulating layer 125 may include different materials from each other. in an embodiment, for example, the first organic insulating layer 123 may include a siloxane resin, and the second organic insulating layer 125 may include a polyimide resin. Alternatively, the first organic insulating layer 123 may include a polyimide resin, and the second organic insulating layer 125 may include a siloxane resin. However, the disclosure is not limited thereto. In an alternative embodiment, for example, the first organic insulating layer 123 and the second organic insulating layer 125 may include a same material as each other.

A first connection electrode CNE1 may be disposed on the fifth insulating layer 121. The first connection electrode CNE1 may be connected to the connection signal line SCL through a contact hole CNT defined in the first insulating layer 113 to the fifth insulating layer 121.

A second connection electrode CNE2 may be disposed on the first organic insulating layer 123. The second connection electrode CNE2 may be connected to the first connection electrode CNE1 through a first via hole VIA1 defined in the first organic insulating layer 123.

The light-emitting element OLED may be disposed on the second organic insulating layer 125. In an embodiment, the light-emitting element OLED may be an organic light-emitting diode. The light-emitting element OLED may include the first electrode 210, an intermediate layer 220, and a second electrode 230, which are sequentially stacked one on another. The first electrode 210 may be disposed on the second organic insulating layer 125. In an embodiment, a pixel defining layer 180 may be disposed on the second organic insulating layer 125.

The second organic insulating layer 125 may be disposed on the first electrode 210. The first electrode 210 may be electrically connected to the second connection electrode CNE2 through a second via hole VIA2 defined in the second organic insulating layer 125. The first electrode 210 may include a conductive material, such as ITO, indium zinc oxide (IZO), ZnO, indium oxide (In₂O₃), indium gallium oxide (IGO), or aluminum zinc oxide (AZO). In an embodiment, the first electrode 210 may include a reflective film including silver (Ag), magnesium (Mg), Al, platinum (Pt), palladium (Pd), gold (Au), nickel (Ni), neodymium (Nd), iridium (Ir), chromium (Cr), or a compound thereof. In an embodiment, the first electrode 210 may further include a film including ITO, IZO, ZnO, or In₂O₃ above/below the reflective film stated above. In an embodiment, for example, the first electrode 210 may have a multi-layered structure of ITO/Ag/ITO.

The pixel defining layer 180 in which a first opening 1800P is defined to expose at least a portion of the first electrode 210, may be disposed on the first electrode 210. The first opening 1800P of the pixel defining layer 180 may define an emission area EA of light emitted by the light-emitting element OLED. In an embodiment, for example, a width of the first opening 1800P may correspond to a width of the emission area EA. The periphery of the emission area EA is a non-emission area NEA, and the non-emission area NEA may surround the emission area EA.

The pixel defining layer 180 may include an organic insulating material. Alternatively, the pixel defining layer 180 may include an inorganic insulating material, such as silicon nitride, silicon oxynitride, or silicon oxide. Alternatively, the pixel defining layer 180 may include an organic insulating material and an inorganic insulating material. In an embodiment, the pixel defining layer 180 may include a light-blocking material and may be provided in black. The light-blocking material may include carbon black, carbon nanotubes, a resin or paste including a black dye, metal particles, such as nickel, aluminum, molybdenum, and alloys thereof, metal oxide particles (e.g., chromium oxide), metal nitride particles (e.g., chromium nitride), or the like. In an embodiment where the pixel defining layer 180 includes a light-blocking material, reflection of external light by metal structures on a lower portion of the pixel defining layer 180 may be reduced.

Although not illustrated in FIG. 5, a spacer may be disposed on the pixel defining layer 180. The spacer may include an organic insulating material, such as polyimide. Alternatively, the spacer may include an inorganic insulating material, such as silicon nitride or silicon oxide, or may include an organic insulating material and an inorganic insulating material.

In an embodiment, the spacer may include a same material as that of the pixel defining layer 180. In such an embodiment, the pixel defining layer 180 and the spacer may be formed together in a mask operation using a halftone mask or the like. However, the disclosure is not limited thereto. In an alternative embodiment, for example, the spacer and the pixel defining layer 180 may include different materials from each other.

The intermediate layer 220 may be disposed on the first electrode 210. The intermediate layer 220 may include a first functional layer 220a, an emission layer 220b, and a second functional layer 220c, which are sequentially stacked one on another. The first functional layer 220a and the second functional layer 220c may be collectively referred to as an organic functional layer 220e.

The emission layer 220b may be arranged in the first opening 1800P of the pixel defining layer 180. The emission layer 220b may include a polymer organic material or a low-molecular-weight organic material, which emits light of a certain color.

The organic functional layer 220e may include at least one selected from the first functional layer 220a between the first electrode 210 and the emission layer 220b and the second functional layer 220c between the emission layer 220b and the second electrode 230. In an embodiment, for example, the first functional layer 220a may be between the first electrode 210 and the emission layer 220b, and the second functional layer 220c between the emission layer 220b and the second electrode 230 may be omitted. In an embodiment, the first functional layer 220a between the first electrode 210 and the emission layer 220b may be omitted, and the second functional layer 220c may be between the emission layer 220b and the second electrode 230. In an embodiment, the first functional layer 220a may be between the first electrode 210 and the emission layer 220b, and the second functional layer 220c may be between the emission layer 220b and the second electrode 230. Hereinafter, embodiments in which the first functional layer 220a and the second functional layer 220c are respectively arranged will be mainly described in detail.

The first functional layer 220a may include a hole transport layer (HTL), or an HTL and a hole injection layer (HIL). The second functional layer 220c may include an electron transport layer (ETL) and/or an electron injection layer (EIL). The first functional layer 220a and/or the second functional layer 220c may be a common layer formed to entirely cover the substrate 100.

The second electrode 230 may include a conductive material having a low work function. In an embodiment, for example, the second electrode 230 may include a (semi)transparent layer including Ag, Mg, Al, Pt, Pd, Au, Ni, Nd, Ir, Cr, lithium (Li), calcium (Ca), alloys thereof, or the like. Alternatively, the second electrode 230 may further include a layer, such as ITO, IZO, ZnO, or In₂O₃, above the (semi)transparent layer including the above-stated material.

Although not illustrated in FIG. 5, a capping layer may be further disposed on the second electrode 230. The capping layer may include lithium fluoride (LiF), an inorganic material, or/and an organic material.

The encapsulation layer 300 may be disposed on the light-emitting element OLED. The encapsulation layer 300 may include a thin-film encapsulation layer or an encapsulation substrate. Hereinafter, embodiments in which the encapsulation layer 300 includes a thin-film encapsulation layer will be mainly described in detail.

In an embodiment, the encapsulation layer 300 may include at least one inorganic film layer and at least one organic film layer. In an embodiment, for example, the encapsulation layer 300 may include a first inorganic film layer 310, an organic film layer 320, and a second inorganic film layer 330, which are sequentially stacked.

The first inorganic film layer 310 may be directly disposed on the second electrode 230. The first inorganic film layer 310 may prevent or minimize penetration of external moisture or oxygen into the light-emitting element OLED.

The organic film layer 320 may be directly disposed on the first inorganic film layer 310. The organic film layer 320 may provide a flat surface on the first inorganic film layer 310. Curves or particles formed on an upper surface of the first inorganic film layer 310 are covered by the organic film layer 320, so that the influence of a surface state of the upper surface of the first inorganic film layer 310 on components disposed on the organic film layer 320 may be blocked.

The second inorganic film layer 330 may be directly disposed on the organic film layer 320. The second inorganic film layer 330 may prevent or minimize moisture or the like emitted from the organic film layer 320 from being emitted to the outside.

The first inorganic film layer 310 and the second inorganic film layer 330 may each include one or more inorganic materials, such as aluminum oxide, titanium oxide, tantalum oxide, hafnium oxide, zinc oxide, silicon oxide, silicon nitride, or silicon oxynitride. The first inorganic film layer 310 and the second inorganic film layer 330 may each be a single layer or a multi-layer, each layer therein including at least one selected from the materials described above. The organic film layer 320 may include a polymer-based material. The polymer-based material may include an acrylic-based resin, an epoxy-based resin, polyimide, polyethylene, or the like.

The input sensing layer 400 may be disposed on the encapsulation layer 300. The input sensing layer 400 may include a first sensing insulating layer 410, a first conductive pattern 420, a second sensing insulating layer 430, a second conductive pattern 440, and a third sensing insulating layer 450.

The first sensing insulating layer 410 may be disposed on the encapsulation layer 300. In addition, the first conductive pattern 420 may be disposed on the first sensing insulating layer 410, and may be covered by the second sensing insulating layer 430. In addition, the second conductive pattern 440 may be disposed on the second sensing insulating layer 430, and may be covered by the third sensing insulating layer 450. Each of the first sensing insulating layer 410, the second sensing insulating layer 430, and the third sensing insulating layer 450 may include at least one selected from an inorganic material and an organic material.

Each of the first conductive pattern 420 and the second conductive pattern 440 may have conductivity. Each of the first conductive pattern 420 and the second conductive pattern 440 may be provided as a single layer or as a plurality of layers. In addition, at least one of the first conductive pattern 420 and the second conductive pattern 440 may be provided as mesh lines in a plan view.

The mesh lines configuring the first conductive pattern 420 and the second conductive pattern 440 may not overlap the emission layer 220b in a plan view. Accordingly, in an embodiment where the input sensing layer 400 is directly formed on the light-emitting element OLED, light emitted by the emission layer 220b of the light-emitting element OLED may be provided to a user without interference from the input sensing layer 400.

In an embodiment where the light-blocking layer 510 is directly formed on the second conductive pattern 440, at least a portion of the second conductive pattern 440 may be damaged during an operation of patterning the light-blocking layer 510. Accordingly, damage to the second conductive pattern 440 may be prevented or minimized by arranging the third sensing insulating layer 450 between the second conductive pattern 440 and the light-blocking layer 510.

The filter layer 500 may be disposed on the input sensing layer 400. The filter layer 500 may include the light-blocking layer 510, a color filter layer 520, and an overcoat layer 530. In an embodiment, the color filter layer 520 may be disposed on the input sensing layer 400. The color filter layer 520 may at least partially overlap the emission layer 220b of the intermediate layer 220 therebelow. The color filter layer 520 may selectively transmit light corresponding to light provided by the emission layer 220b. In an embodiment, for example, when the emission layer 220b provides blue light, the color filter layer 520 may be a blue color filter that transmits blue light. Alternatively, when the emission layer 220b provides green light, the color filter layer 520 may be a green color filter that transmits green light. Alternatively, when the emission layer 220b provides red light, the color filter layer 520 may be a red color filter that transmits red light.

The color filter layer 520 may include a polymer photosensitive resin and a pigment or dye. In an embodiment, for example, the color filter layer 520 overlapping the emission layer 220b for providing blue light may include a blue pigment or dye, the color filter layer 520 overlapping the emission layer 220b for providing green light may include a green pigment or dye, and the color filter layer 520 overlapping the emission layer 220b for providing red light may include a red pigment or dye.

However, the disclosure is not limited thereto. In an alternative embodiment, the color filter layer 520 overlapping the emission layer 220b for providing blue light may not include a pigment or dye. In such an embodiment, the color filter layer 520 may be transparent, and the color filter layer 520 may include a transparent photosensitive resin.

The light-blocking layer 510 may be between color filter layers 520 providing different colors of light. The light-blocking layer 510 is a pattern having a black color, and may be a grid-shaped matrix. The light-blocking layer 510 may include a black coloring agent. The black coloring agent may include a black dye and a black pigment. The black coloring agent may include carbon black, a metal, such as chromium, or an oxide thereof. In an embodiment, the light-blocking layer 510 may include a same material as that of the pixel defining layer 180.

In an embodiment, the light-blocking layer 510 may define a second opening 5100P overlapping the emission area EA of the light-emitting element OLED. A width of the second opening 5100P of the light-blocking layer 510 may be equal to or greater than a width of the emission area EA of the light-emitting element OLED and/or the first opening 1800P of the pixel defining layer 180. However, the disclosure is not limited thereto. In an embodiment, at least a portion of the color filter layer 520 may be arranged (or positioned) in the second opening 5100P defined in the light-blocking layer 510.

The overcoat layer 530 may be disposed on the light-blocking layer 510 and the color filter layer 520. The overcoat layer 530 is a transparent layer that does not have a color in a visible light band, and may provide a flat upper surface while covering irregularities generated in an operation of forming the light-blocking layer 510 and the color filter layer 520. In an embodiment, for example, the overcoat layer 530 may include a transparent organic material, such as an acrylic resin.

In an embodiment, the window 600 may be disposed on the filter layer 500. This will be described below in greater detail with reference to FIG. 6.

FIG. 6 is a schematic cross-sectional view of the window 600 in a display device according to an embodiment.

Referring to FIG. 6, the window 600 may include a window substrate 610, a first layer 620, a second layer 630, a third layer 640, and an anti-fingerprint layer 650, which are sequentially stacked one on another. In an embodiment, the first layer 620, the second layer 630, and the third layer 640 may correspond to a low-refractive-index layer, a high-refractive-index layer, and a low-refractive-index layer, respectively. In such an embodiment where a low-refractive-index layer, a high-refractive-index layer, and a low-refractive-index layer are sequentially arranged on the window substrate 610, reflected external light rays destructively interfere with each other, and thus, reflectance of the window 600 may be reduced. In such an embodiment, reflectance of the display device 1 including the window 600 may be reduced, and accordingly, visibility of the display device 1 may be improved. This will be described below in greater detail.

In an embodiment, the window substrate 610 may include glass or a polymer resin. In an embodiment where the window substrate 610 includes a polymer resin, the window substrate 610 may include at least one material selected from polyethersulfone, polyacrylate, polyetherimide, polyethylene naphthalate, polyethylene terephthalate, polyphenylene sulfide, polyarylate, polyimide, polycarbonate, cellulose triacetate, cellulose acetate propionate, polyarylene ether sulfone, benzocyclobutene, hexamethyldisiloxane, and polymethyl methacrylate.

In an embodiment, a refractive index n1 of the window substrate 610 may be about 1.51. In more particular, the refractive index n1 of the window substrate 610 with respect to a wavelength of 550 nanometers (nm) may be about 1.51.

The first layer 620 may be disposed on the window substrate 610. The first layer 620 may correspond to a low-refractive-index layer. In an embodiment, for example, a refractive index n2 of the first layer 620 may be in a range of about 1.2 to about 1.4. In more particular, the refractive index n2 of the first layer 620 with respect to a wavelength of 550 nm may be in a range of about 1.2 to about 1.4. If the refractive index n2 of the first layer 620 is less than 1.2, the refractive index n2 of the first layer 620 is similar to a refractive index of air, and thus, reflected external light rays that destructively interfere with each other among reflected external light rays may be reduced. In an embodiment, the refractive index n2 of the first layer 620 as a low-refractive-index layer is less than the refractive index n3 of the second layer 630 as a high-refractive-index layer, and a difference between the refractive index n2 of the first layer 620 and the refractive index n3 of the second layer 630 is significantly great, i.e., greater than a predetermined value, so that the reflectance of the window 600 may be reduced. If the refractive index n2 of the first layer 620 is greater than 1.4, because there is no significant difference between the refractive index n2 of the first layer 620 and the refractive index n3 of the second layer 630, reflected external light rays that destructively interfere with each other among reflected external light rays may be reduced, and thus, the reflectance of the window 600 may not be reduced. Accordingly, in an embodiment where the refractive index n2 of the first layer 620 is provided in a range of about 1.2 to about 1.4, because the refractive index n2 of the first layer 620 and the refractive index n3 of the second layer 630 have a significant difference, reflected external light rays that destructively interfere with each other among reflected external light rays may be increased, and thus, the reflectance of the window 600 may be reduced. Accordingly, the reflectance of the display device 1 including the window 600 may be reduced, and thus, the visibility of the display device 1 may be improved.

In an embodiment, the first layer 620 may have a thickness t1 in a range of about 50 nm to about 150 nm. If the thickness t1 of the first layer 620 is less than 50 nm, a bonding strength between the window substrate 610 and the first layer 620 and a bonding strength between the first layer 620 and the second layer 630 are low, and thus, the first layer 620 may be peeled off from the window substrate 610 and/or the second layer 630. If the thickness t1 of the first layer 620 is greater than 150 nm, because the thickness t1 of the first layer 620 is too thick, reflected external light rays that destructively interfere with each other among reflected external light rays may be reduced, and thus, the reflectance of the window 600 may increase. Accordingly, In an embodiment, the thickness t1 of the first layer 620 is provided in a range of about 50 nm to about 150 nm, such that peeling off of the first layer 620 from the window substrate 610 and/or the second layer 630 may be prevented, and the reflectance of the window 600 may be reduced due to an increase in reflected external light rays that destructively interfere with each other among reflected external light rays. Accordingly, the reflectance of the display device 1 including the window 600 may be reduced, and accordingly, the visibility of the display device 1 may be improved.

In an embodiment, the first layer 620 may include at least one selected from silica, fused silica, fluorine-doped fused silica, magnesium fluoride (MgF₂), calcium fluoride (CaF₂), aluminum fluoride (AlF₃), and ytterbium fluoride (YbF₃). In an embodiment, for example, the first layer 620 may include magnesium fluoride (MgF₂). In an embodiment, magnesium fluoride (MgF₂) in the first layer 620 may have a crystalline structure at about 200° C. to about 300° C. In more particular, magnesium fluoride (MgF₂) in the first layer 620 may have a crystalline structure at about 250° C.

The second layer 630 may be disposed on the first layer 620. The second layer 630 may correspond to a high-refractive-index layer. In an embodiment, for example, the refractive index n3 of the second layer 630 may be greater than the refractive index n2 of the first layer 620 and a refractive index n4 of the third layer 640. In an embodiment, for example, the refractive index n3 of the second layer 630 may be about 1.6 to about 2.0. In more particular, the refractive index n3 of the second layer 630 at a wavelength of 550 nm may be about 1.6 to about 2.0. If the refractive index n3 of the second layer 630 is less than 1.6, there is no significant difference between the refractive index n3 of the second layer 630 and the refractive index n2 of the first layer 620 and between the refractive index n3 of the second layer 630 and the refractive index n4 of the third layer 640, reflected external light rays that destructively interfere with each other among reflected external light rays may be reduced, and thus, reflectance of the window 600 may not be reduced. Accordingly, In an embodiment where the refractive index n3 of the second layer 630 is provided in a range of about 1.6 to about 2, there is a significant difference between the refractive index n3 of the second layer 630 and the refractive index n2 of the first layer 620 and between the refractive index n3 of the second layer 630 and the refractive index n3 of the third layer 640, reflected external light rays that destructively interfere with each other among reflected external light rays may increase, and thus, the reflectance of the window 600 may be reduced. Accordingly, the reflectance of the display device 1 including the window 600 may be reduced, and accordingly, the visibility of the display device 1 may be improved.

In an embodiment, the second layer 630 may have a thickness t2 in a range of about 5 nm to about 15 nm. If the thickness t2 of the second layer 630 is less than 5 nm, a bonding strength between the first layer 620 and the second layer 630 and a bonding strength of the second layer 630 and the third layer 640 are low, and thus, the second layer 630 may be peeled off from the first layer 620 and/or the third layer 640. If the thickness t2 of the second layer 630 is greater than 15 nm, because the thickness t2 of the second layer 630 is too thick, reflected external light rays that destructively interfere with each other among reflected external light rays may be reduced, and thus, the reflectance of the window 600 may increase. Accordingly, in an embodiment where the thickness t2 of the second layer 630 is provided in a range of about 5 nm to about 15 nm, peeling off of the second layer 630 from the first layer 620 and/or the third layer 640 may be prevented, and the reflectance of the window 600 may be reduced due to an increase in reflected external light rays that destructively interfere with each other among reflected external light rays. Accordingly, the reflectance of the display device 1 including the window 600 may be reduced, and accordingly, the visibility of the display device 1 may be improved.

In an embodiment, the second layer 630 may include at least one selected from (e.g., one of) zirconium oxide (ZrO₂), hafnium oxide (HfO₂), tantalum oxide (Ta₂O₅), niobium oxide (Nb₂O₅), titanium oxide (TiO₂), yttrium oxide (Y₂O₃), silicon nitride (Si₃N₄), strontium titanate (SrTiO₃), tungsten oxide (WO₃), and chromium oxide (Cr₂O₃). For example, the second layer 630 may include chromium oxide (Cr₂O₃). In an embodiment, where the second layer 630 includes chromium oxide (Cr₂O₃), chromium in the second layer 630 may be trivalent chromium (Cr³⁺). In an embodiment, the second layer 630 may include at least one selected from the materials described above and silicon (Si). In an embodiment, for example, the second layer 630 may include chromium oxide (Cr₂O₃) and silicon (Si), and chromium oxide (Cr₂O₃) and silicon (Si) may form a covalent bond. In an embodiment, the second layer 630 may include chromium oxide (Cr₂O₃) covalently bonded to silicon (Si).

The third layer 640 may be disposed on the second layer 630. The third layer 640 may correspond to a low-refractive-index layer. In an embodiment, for example, the refractive index n4 of the third layer 640 may be less than the refractive index n3 of the second layer 630. In an embodiment, for example, the refractive index of the third layer 640 may be in a range of about 1.4 to about 1.6. In particular, the refractive index n4 of the third layer 640 at a wavelength of 550 nm may be in a range of about 1.4 to about 1.6. If the refractive index n4 of the third layer 640 is less than 1.4, because the refractive index n4 of the third layer 640 is less than a refractive index n5 of the anti-fingerprint layer 650, reflected external light rays that destructively interfere with each other among reflected external light rays may be reduced, and thus, the reflectance of the window 600 may not be reduced. If the refractive index n4 of the third layer 640 is greater than 1.6, because the refractive index n4 of the third layer 640 is greater than the refractive index n3 of the second layer 630 as a high-refractive-index layer, reflected external light rays that destructively interfere with each other among reflected external light rays may be reduced, and thus, the reflectance of the window 600 may not be reduced. Accordingly, in an embodiment where the refractive index n4 of the third layer 640 is provided in a range of about 1.4 to about 1.6, because the refractive index n4 of the third layer 640 as a low-refractive-index layer is less than the refractive index n3 of the second layer 630 as a high-refractive-index layer, reflected external light rays that destructively interfere with each other among reflected external light rays may be increased, and thus, the reflectance of the window 600 may be reduced. Accordingly, the reflectance of the display device 1 including the window 600 may be reduced, and thus, the visibility of the display device 1 may be improved.

In an embodiment, the third layer 640 may have a thickness t3 in a range of about 5 nm to about 15 nm. If the thickness t3 of the third layer 640 is less than 5 nm, a bonding strength between the third layer 640 and the second layer 630 and a bonding strength between the third layer 640 and the anti-fingerprint layer 650 are low, and thus, the third layer 640 may be peeled off from the second layer 630 and/or the anti-fingerprint layer 650. If the thickness t3 of the third layer 640 is greater than 15 nm, because the thickness t3 of the third layer 640 is too thick, reflected external light rays that destructively interfere with each other among reflected external light rays may be reduced, and thus, the reflectance of the window 600 may increase. Accordingly, in an embodiment where the thickness t3 of the third layer 640 is provided in a range of about 5 nm to about 15 nm, peeling off of the third layer 640 from the second layer 630 and/or the anti-fingerprint layer 650 may be prevented, and the reflectance of the window 600 may be reduced due to an increase in reflected external light rays that destructively interfere with each other among reflected external light rays. Accordingly, the reflectance of the display device 1 including the window 600 may be reduced, and accordingly, the visibility of the display device 1 may be improved.

In an embodiment, the third layer 640 may include silicon oxide (SiO₂). However, the disclosure is not limited thereto.

Generally, because magnesium fluoride (MgF₂) has a weak bonding strength with other materials, when the anti-fingerprint layer 650 is directly disposed on the first layer 620 including magnesium fluoride (MgF₂), a bonding strength between the first layer 620 and the anti-fingerprint layer 650 is weak, the anti-fingerprint layer 650 may be easily peeled off from the first layer 620, and thus, the wear-resistance of the window 600 may be reduced.

In an embodiment, the third layer 640 including silicon oxide (SiO₂) is arranged between the first layer 620 and the anti-fingerprint layer 650, such that a bonding strength between the first layer 620 and the anti-fingerprint layer 650 may be increased, and accordingly, the wear-resistance of the window 600 may be improved. In an embodiment, the third layer 640 including silicon oxide (SiO₂) may be arranged between the first layer 620 and the anti-fingerprint layer 650, and the second layer 630 including chromium oxide (Cr₂O₃) covalently bonded to silicon (Si) may be arranged between the first layer 620 and the third layer 640. In such an embodiment, as the second layer 630 is arranged between the first layer 620 and the third layer 640, a bonding strength between the first layer 620 and the third layer 640 may be increased, and accordingly, the wear-resistance of the window 600 may be improved. That is, by arranging the second layer 630 and the third layer 640 between the first layer 620 and the anti-fingerprint layer 650, a bonding strength between respective layers may be increased, and accordingly, the wear-resistance of the window 600 may be improved.

The anti-fingerprint layer 650 may be disposed on the third layer 640. In an embodiment, the refractive index n5 of the anti-fingerprint layer 650 may be less than the refractive index n4 of the third layer 640. In an embodiment, for example, the refractive index n5 of the anti-fingerprint layer 650 may be about 1.32. In more particular, the refractive index n5 of the anti-fingerprint layer 650 with respect to a wavelength of 550 nm may be about 1.32.

In an embodiment, the anti-fingerprint layer 650 may have a thickness t4 in a range of about 5 nm to about 30 nm. If the thickness t4 of the anti-fingerprint layer 650 is less than 5 nm, a bonding strength between the anti-fingerprint layer 650 and the third layer 640 is low, and thus, the anti-fingerprint layer 650 may be peeled off from the third layer 640. If the thickness t4 of the anti-fingerprint layer 650 is greater than 30 nm, because the thickness t4 of the anti-fingerprint layer 650 is too thick, an uppermost layer of the anti-fingerprint layer 650 may be peeled off, and thus, the wear-resistance of the window 600 including the anti-fingerprint layer 650 may be reduced. Accordingly, in an embodiment where the thickness t4 of the anti-fingerprint layer 650 is provided in a range of about 5 nm to about 30 nm, the anti-fingerprint layer 650 may be prevented from being peeled off from the third layer 640, and deterioration of the wear-resistance of the anti-fingerprint layer 650 may be prevented or minimized.

In an embodiment, the anti-fingerprint layer 650 may include perfluoropolyether (PFPE). An end of the anti-fingerprint layer 650 may be bonded to the third layer 640. Accordingly, a bonding strength between the anti-fingerprint layer 650 and the third layer 640 may be increased.

In an embodiment, as described above, layers having a difference in refractive index, such as a low-refractive-index layer/a high-refractive-index layer/a low-refractive-index layer, are sequentially stacked, such that a phase difference may occur in light rays reflected from respective layers due to a difference in refractive index of the layers, and thus, the amplitudes of respective layers overlap and the amount of reflected light rays may be reduced. In an embodiment, for example, a phase of the reflected light rays from respective layers may be changed by λ/4, and thus, the amplitudes of the reflected light rays may overlap, and the overall reflectance may be reduced.

In an embodiment, the window 600 may include the window substrate 610, the first layer 620, the second layer 630, the third layer 640, and the anti-fingerprint layer 650, which are sequentially stacked one on another. In such an embodiment, the first layer 620 may correspond to a low-refractive-index layer, the second layer 630 may correspond to a high-refractive-index layer, and the third layer 640 may correspond to a low-refractive-index layer. A phase of light reflected from each layer may change due to a difference in refractive index between the first layer 620, the second layer 630, and the third layer 640, and thus, the amplitudes of the reflected light rays offset each other, thereby reducing the amount of reflected light rays. That is, reflectance may be reduced.

TABLE 1

| | Reflection characteristics | | |
|---|---|---|---|
| | Reflectance (%) | a* | |
| Embodiment | 5.79 | 0.17 | −0.28 |
| Comparative | 8 | 0 | 0 |
| Example 1 | | | |
| Comparative | 5.97 | 0.27 | −2.25 |
| Example 2 | | | |

Table 1 is a table showing the evaluation results of the reflection characteristics of windows according to an embodiment, Comparative Example 1, and Comparative Example 2. In Table 1, the embodiment corresponds to a case in which the window 600 includes the window substrate 610, the first layer 620, the second layer 630, the third layer 640, and the anti-fingerprint layer 650, which are sequentially stacked one on another, and the window substrate 610, the first layer 620, the second layer 630, the third layer 640, and the anti-fingerprint layer 650 include glass, magnesium fluoride (MgF₂), chromium oxide (Cr₂O₃) covalently bonded to silicon (Si), and PFPE, respectively. Comparative Example 1 is a case in which the window 600 includes, the window substrate 610, the third layer 640, and the anti-fingerprint layer 650, which are sequentially stacked one on another, and the window substrate 610, the third layer 640, and the anti-fingerprint layer 650 include glass, silicon oxide (SiO₂), and PFPE, respectively. Comparative Example 2 corresponds to a case in which the window 600 includes the window substrate 610, the first layer 620, the third layer 640, and the anti-fingerprint layer 650, which are sequentially stacked one on another, and the window substrate 610, the first layer 620, the third layer 640, and the anti-fingerprint layer 650 include glass, magnesium fluoride (MgF₂), silicon oxide (SiO₂), and PFPE, respectively. That is, compared with the embodiment, Comparative Example 1 corresponds to a structure that does not include the first layer 620 including magnesium fluoride (MgF₂) and the second layer 630 including chromium oxide (Cr₂O₃) covalently bonded to silicon (Si), and compared with the embodiment, Comparative Example 2 corresponds to a structure that does not include the second layer 630 including chromium oxide (Cr₂O₃) covalently bonded to silicon (Si).

In addition, in Table 1, reflectance means reflectance measured in a specular component included (SCI) mode, and a* and b* mean a* and b* in an L*a*b* color system of light measured in a specular component excluded (SCE) mode, respectively. A case, in which the reflectance is 6.3% or less, a* has a value within −2<a*<2, and b* has a value within −1.5<a*<0.5, corresponds to a case in which a desired (or pre-set) condition is satisfied. In addition, when values are out of the above-mentioned range, it corresponds to a case where a desired condition is not satisfied.

Referring to Table 1, it may be confirmed that the reflectance of the embodiment is the lowest compared to the reflectance of the Comparative Example 1 and Comparative Example 2.

First, in the case of the embodiment, it may be confirmed that the reflectance satisfies 6.3% or less, a* has a value within −2<a*<2, and b* has a value within −1.5<a*<0.5. Accordingly, the embodiment satisfies the desired condition.

However, in the case of Comparative Example 1, because the reflectance exceeds 6.3%, Comparative Example 1 did not satisfy the desired condition. In addition, in the case of Comparative Example 2, although the reflectance and a* satisfy the required condition, b* corresponds to −2.25, and thus, Comparative Example 2 also did not satisfy the desired condition.

Accordingly, an embodiment of the window 600 including the window substrate 610, the first layer 620, the second layer 630, the third layer 640, and the anti-fingerprint layer 650, which are sequentially stacked one on another, where the window substrate 610, the first layer 620, the second layer 630, the third layer 640, and the anti-fingerprint layer 650 include glass, magnesium fluoride (MgF₂), chromium oxide (Cr₂O₃) covalently bonded to silicon (Si), and PFPE, respectively, may have the reflectance and may have a* and b* values of the desired condition.

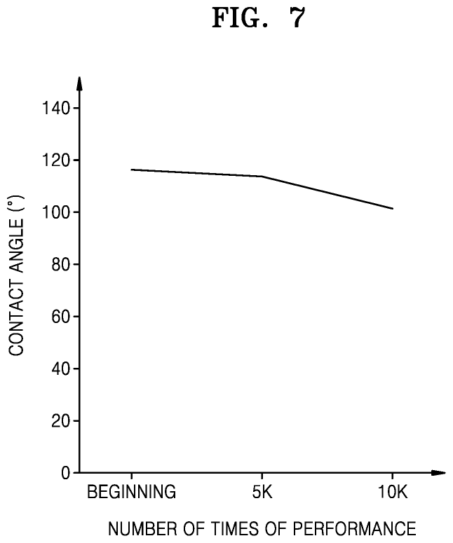

FIG. 7 is a graph illustrating a wear-resistance evaluation result of an embodiment. In FIG. 7, the wear-resistance evaluation was performed by applying a load of 1 Kg to a surface of the window 600 of the embodiment having the structure described above in Table 1 by using an eraser, and then reciprocating by a distance of 15 mm at a speed of 40 cycles/min. Then, a contact angle with respect to water was evaluated by dropping water on the surface of the window 600. When a contact angle with respect to water is 95° or more when the number of times of performance of evaluation is 6000 times or more, it corresponds to a case where the desired wear-resistance condition is satisfied. When a contact angle with respect to water is less than 95°, it corresponds to a case where the desired wear-resistance condition is not required.

Referring to FIG. 7, it may be confirmed that contact angles with respect to water are 116.3°, 113.7°, and 101.4°, respectively, when the wear-resistance evaluation is not performed in the embodiment, when the wear-resistance evaluation is performed 5000 times, and when the wear-resistance evaluation is performed 10000 times. Accordingly, in the case of the embodiment, because the contact angle with respect to water satisfies 95° or more when the wear-resistance evaluation is performed 6000 times or more by using an eraser, the embodiment satisfies the desired wear-resistance condition.

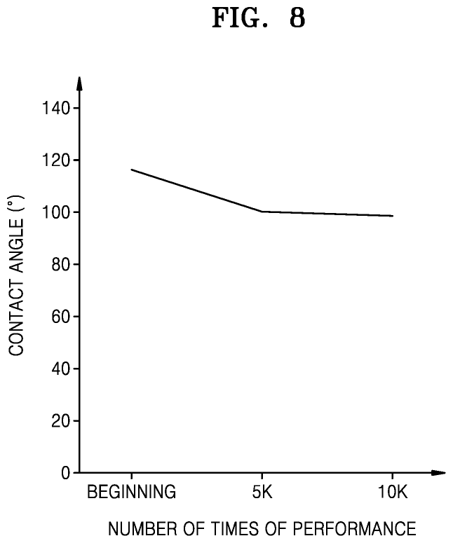

FIG. 8 is a graph illustrating a wear-resistance evaluation result of an embodiment. In FIG. 8, the wear-resistance evaluation was performed by applying a load of 1 Kg to a surface of the window 600 of the embodiment having the structure described above in Table 1 by using a steel wool, and then reciprocating by a distance of 15 mm at a speed of 40 cycles/min. Then, a contact angle with respect to water was evaluated by dropping water on the surface of the window 600. When a contact angle with respect to water is 95° or more when the number of performing evaluation is 6000 times or more, it corresponds to a case where the desired wear-resistance condition is satisfied. When a contact angle with respect to water is less than 95°, it corresponds to a case where the desired wear-resistance condition is not required.

Referring to FIG. 8, it may be confirmed that contact angles with respect to water are 116.3°, 100.2°, and 98.6°, respectively, when the wear-resistance evaluation is not performed in the embodiment, when the wear-resistance evaluation is performed 5000 times, and when the wear-resistance evaluation is performed 10000 times. Accordingly, in the case of the embodiment, because the contact angle with respect to water satisfies 95° or more when the wear-resistance evaluation is performed 6000 times or more by using a steel wool, the embodiment satisfies a desired wear-resistance condition.

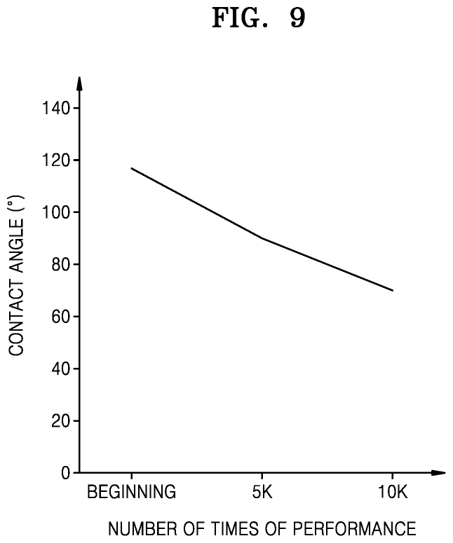

FIG. 9 is a graph illustrating a wear-resistance evaluation result of Comparative Example 1. In FIG. 9, the wear-resistance evaluation was performed by applying a load of 1 Kg to a surface of the window 600 of Comparative Example 1 having the structure described above in Table 1 by using an eraser, and then reciprocating by a distance of 15 mm at a speed of 40 cycles/min. Then, a contact angle with respect to water was evaluated by dropping water on the surface of the window 600. When a contact angle with respect to water is 95° or more when the number of performing evaluation is 6000 times or more, it corresponds to a case where the desired wear-resistance condition is satisfied. When a contact angle with respect to water is less than 95°, it corresponds to a case where the desired wear-resistance condition is not satisfied.

Referring to FIG. 9, it may be confirmed that contact angles with respect to water are 116.8°, 90°, and 70°, respectively, when the wear-resistance evaluation is not performed in Comparative Example 1, when the wear-resistance evaluation is performed 5000 times, and when the wear-resistance evaluation is performed 10000 times. Accordingly, in the case of Comparative Example 1, because the contact angle with respect to water is less than 95° when the wear-resistance evaluation is performed 6000 times or more by using an eraser, Comparative Example 1 does not satisfy the desired wear-resistance condition.

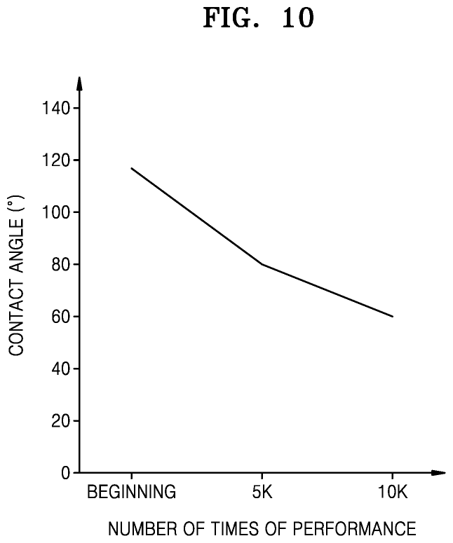

FIG. 10 is a graph illustrating a wear-resistance evaluation result of Comparative Example 1. In FIG. 10, the wear-resistance evaluation was performed by applying a load of 1 Kg to a surface of the window 600 of Comparative Example 1 having the structure described above in Table 1 by using a steel wool, and then reciprocating by a distance of 15 mm at a speed of 40 cycles/min. Then, a contact angle with respect to water was evaluated by dropping water on the surface of the window 600. When a contact angle with respect to water is 95° or more when the number of performing evaluation is 6000 times or more, it corresponds to a case where the desired wear-resistance condition is satisfied. When a contact angle with respect to water is less than 95°, it corresponds to a case where the desired wear-resistance condition is not required.

Referring to FIG. 10, it may be confirmed that contact angles with respect to water are 116.8°, 80°, and 60°, respectively, when the wear-resistance evaluation is not performed in Comparative Example 1, when the wear-resistance evaluation is performed 5000 times, and when the wear-resistance evaluation is performed 10000 times. Accordingly, in the case of Comparative Example 1, because the contact angle with respect to water is less than 95° when the wear-resistance evaluation is performed 6000 times or more by using a steel wool, Comparative Example 1 does not satisfy the desired wear-resistance condition.

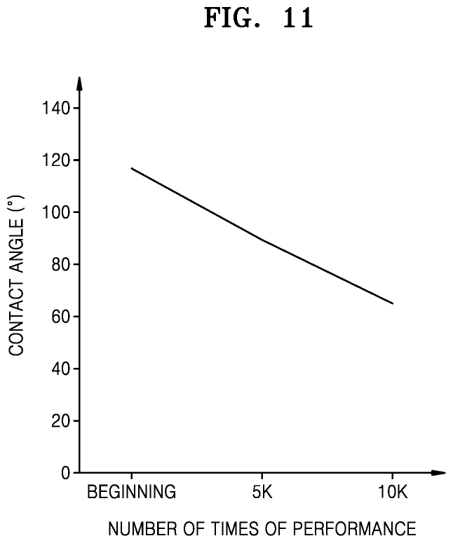

FIG. 11 is a graph illustrating a wear-resistance evaluation result of Comparative Example 2. In FIG. 11, the wear-resistance evaluation was performed by applying a load of 1 Kg to a surface of the window 600 of Comparative Example 2 having the structure described above in Table 1 by using an eraser, and then reciprocating by a distance of 15 mm at a speed of 40 cycles/min. Then, a contact angle with respect to water was evaluated by dropping water on the surface of the window 600. When a contact angle with respect to water is 95° or more when the number of performing evaluation is 6000 times or more, it corresponds to a case where the desired wear-resistance condition is satisfied. When a contact angle with respect to water is less than 95°, it corresponds to a case where the desired wear-resistance condition is not required.

Referring to FIG. 11, it may be confirmed that contact angles with respect to water are 116.8°, 89.4°, and 65°, respectively, when the wear-resistance evaluation is not performed in Comparative Example 2, when the wear-resistance evaluation is performed 5000 times, and when the wear-resistance evaluation is performed 10000 times. Accordingly, in the case of Comparative Example 2, because the contact angle with respect to water is less than 95° when the wear-resistance evaluation is performed 6000 times or more by using an eraser, Comparative Example 2 does not satisfy the desired wear-resistance condition.

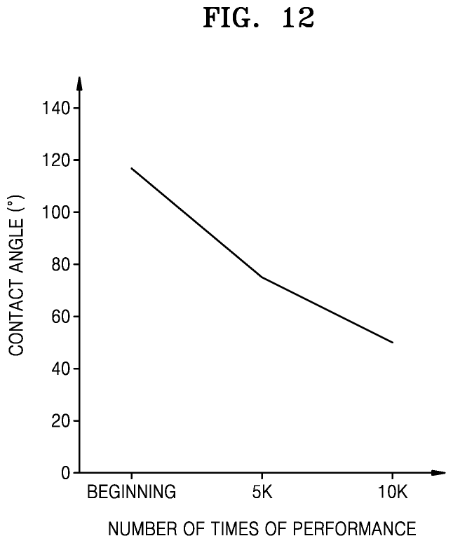

FIG. 12 is a graph illustrating a wear-resistance evaluation result of Comparative Example 2. In FIG. 12, the wear-resistance evaluation was performed by applying a load of 1 Kg to a surface of the window 600 of Comparative Example 2 having the structure described above in Table 1 by using a steel wool, and then reciprocating by a distance of 15 mm at a speed of 40 cycles/min. Then, a contact angle with respect to water was evaluated by dropping water on the surface of the window 600. When a contact angle with respect to water is 95° or more when the number of performing evaluation is 6000 times or more, it corresponds to a case where the desired wear-resistance condition is satisfied. When a contact angle with respect to water is less than 95°, it corresponds to a case where the desired wear-resistance condition is not required.

Referring to FIG. 12, it may be confirmed that contact angles with respect to water are 116.8°, 75°, and 50°, respectively, when the wear-resistance evaluation is not performed in Comparative Example 2, when the wear-resistance evaluation is performed 5000 times, and when the wear-resistance evaluation is performed 10000 times. Accordingly, in the case of Comparative Example 2, because the contact angle with respect to water is less than 95° when the wear-resistance evaluation is performed 6000 times or more by using a steel wool, Comparative Example 2 does not satisfy the desired wear-resistance condition.

Referring to FIGS. 7 to 12, as a result of the wear-resistance evaluation, it may be confirmed that the windows including the structures of Comparative Example 1 and Comparative 2 do not have the wear-resistance of the desired condition, but the window 600 having the structure of the embodiment has the wear-resistance of the desired condition. Compared with the embodiment, Comparative Example 1 corresponds to a structure that does not include the first layer 620 including magnesium fluoride (MgF₂) and the second layer 630 including chromium oxide (Cr₂O₃) covalently bonded to silicon (S1), and compared with the embodiment, Comparative Example 2 corresponds to a structure that does not include the second layer 630 including chromium oxide (Cr₂O₃) covalently bonded to silicon (Si). Accordingly, it may be confirmed that the wear-resistance of the window 600 is improved in a case where the second layer 630 including chromium oxide (Cr₂O₃) covalently bonded to silicon (Si) is arranged between the first layer 620 including magnesium fluoride (MgF₂) and the third layer 640 including silicon oxide (SiO₂).

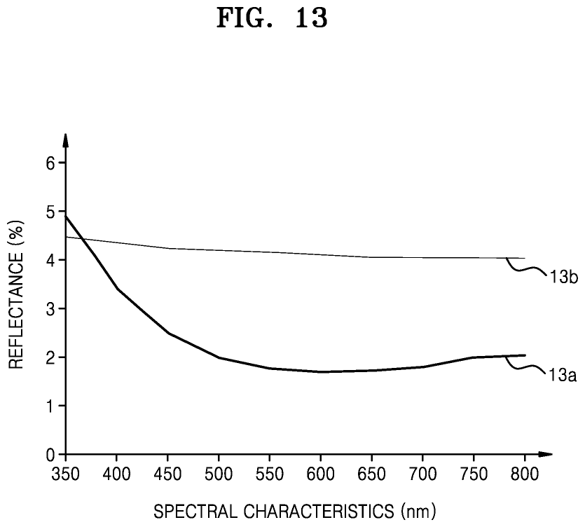

FIG. 13 is a graph illustrating reflectance measurement results according to wavelengths of an embodiment and a window substrate. In particular FIG. 13 includes a graph 13a showing reflectance measurement results of the window 600 having the structure of the embodiment described above in Table 1 in a visible ray wavelength area and a graph 13b showing reflectance measurement results of the window substrate 610 in a visible ray wavelength area.

Referring to FIG. 13, it may be confirmed that the reflectance of the embodiment in the visible ray wavelength area is lower than the reflectance of the window substrate 610 in the visible ray wavelength area. Accordingly, in an embodiment where the window 600 includes a structure in which the first layer 620 including magnesium fluoride (MgF₂), the second layer 630 including chromium oxide (Cr₂O₃) covalently bonded to silicon (Si), the third layer 640 including silicon oxide (SiO₂), and the anti-fingerprint layer 650 including PFPE are sequentially stacked on the window substrate 610, the reflectance thereof in the visible ray area may be reduced.

In an embodiment where the filter layer 500 including the color filter layer 520 is disposed on a light-emitting element, the efficiency of a display device may be improved compared to a case where an optical functional layer including a polarizing plate is disposed on a light-emitting element. However, in a case where the filter layer 500 including the color filter layer 520 is disposed on a light-emitting element the reflectance of external light may increase, and thus, visibility of a user may be deteriorated and display quality may be deteriorated due to reflected external light, compared to a case where an optical functional layer including a polarizing plate is disposed on a light-emitting element.

In an embodiment, the filter layer 500 including the color filter layer 520 is disposed on a light-emitting element, such that the efficiency of the display device 1 may be improved. In such an embodiment, the window 600 has a structure in which the first layer 620 including magnesium fluoride (MgF₂), the second layer 630 including chromium oxide (Cr₂O₃) covalently bonded to silicon (Si), the third layer 640 including silicon oxide (SiO₂), and the anti-fingerprint layer 650 including PFPE are sequentially stacked, such that reflected external light rays destructively interfere with each other, and thus, the reflectance of the window 600 may be reduced, At the same time, the reflectance of the display device 1 including the window 600 may be reduced, and accordingly, the visibility of the display device 1 may be improved.

According to an embodiment of the disclosure described above, deterioration in visibility of a display device due to reflection of external light may be prevented or minimized. In such an embodiment, by improving a bonding strength between layers, the wear-resistance characteristic of a window including the layers may be improved.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A window comprising:
a window substrate;
a first layer disposed on the window substrate, wherein the first layer has a refractive index in a range of about 1.2 to about 1.4;
a second layer disposed on the first layer, wherein the second layer comprises chromium oxide (Cr₂O₃);
a third layer disposed on the second layer, wherein the third layer has a refractive index in a range of about 1.4 to about 1.6; and
an anti-fingerprint layer disposed on the third layer, wherein the anti-fingerprint layer comprises perfluoropolyether (PFPE).

2. The window of claim 1, wherein the second layer has a refractive index which is greater than a refractive index of the first layer and a refractive index of the third layer.

3. The window of claim 2, wherein the second layer has a refractive index in a range of about 1.6 to about 2.0.

4. The window of claim 1, wherein
the first layer has a thickness in a range of about 50 nm to about 150 nm,
the second layer has a thickness in a range of about 5 nm to about 15 nm, and
the third layer has a thickness in a range of about 5 nm of about 15 nm.

5. The window of claim 1, wherein
the first layer comprises magnesium fluoride (MgF₂), and
the third layer comprises silicon oxide (SiO₂).

6. The window of claim 1, wherein the second layer comprises chromium oxide (Cr₂O₃) covalently bonded to silicon (Si).

7. The window of claim 1, wherein a contact angle of a surface of the window with respect to water is about 95° or more after applying a load of 1 kg to the surface of the window by using an eraser and then reciprocating by a distance of 15 mm at a speed of 40 cycles/min for 6000 times.

8. A window comprising:
a window substrate;
a first layer disposed on the window substrate, wherein the first layer has a refractive index in a range of about 1.2 to about 1.4;
a second layer disposed on the first layer, wherein the second layer has a refractive index in a range of about 1.6 to about 2.0;
a third layer disposed on the second layer, wherein the third layer has a refractive index in a range of about 1.4 to about 1.6; and
an anti-fingerprint layer disposed on the third layer, wherein the anti-fingerprint layer comprises perfluoropolyether (PFPE),
wherein a contact angle of a surface of the window with respect to water is about 95° or more after applying a load of 1 kg to the surface of the window by using an eraser and then reciprocating by a distance of 15 mm at a speed of 40 cycles/min for 6000 times.

9. The window of claim 8, wherein
the first layer has a thickness in a range of about 50 nm to about 150 nm,
the second layer has a thickness in a range of about 5 nm to about 15 nm, and
the third layer has a thickness in a range of about 5 nm of about 15 nm.

10. The window of claim 8, wherein
the first layer comprises magnesium fluoride (MgF₂),
the second layer comprises chromium oxide (Cr₂O₃), and
the third layer comprises silicon oxide (SiO₂).

11. The window of claim 10, wherein the second layer comprises chromium oxide (Cr₂O₃) covalently bonded to silicon (Si).

12. A display device comprising:
a substrate;
a light-emitting element disposed on the substrate, wherein the light-emitting element comprises a first electrode, a second electrode, and an intermediate layer between the first electrode and the second electrode;
a filter layer disposed on the light-emitting element, wherein the filter layer comprises a color filter layer and a light-blocking layer; and
a window disposed on the filter layer,
wherein the window comprises:
a window substrate;
a first layer disposed on the window substrate, wherein the first layer has a refractive index in a range of about 1.2 to about 1.4;
a second layer disposed on the first layer, wherein the second layer comprises chromium oxide (Cr₂O₃);
a third layer disposed on the second layer, wherein the third layer has a refractive index in a range of about 1.4 to about 1.6; and
an anti-fingerprint layer disposed on the third layer, wherein the anti-fingerprint layer comprises perfluoropolyether (PFPE).

13. The display device of claim 12, wherein the second layer has a refractive index which is greater than a refractive index of the first layer and a refractive index of the third layer.

14. The display device of claim 12, wherein the second layer has a refractive index in a range of about 1.6 to about 2.0.

15. The display device of claim 14, wherein
the first layer has a thickness in a range of about 50 nm to about 150 nm,
the second layer has a thickness in a range of about 5 nm to about 15 nm, and
the third layer has a thickness in a range of about 5 nm of about 15 nm.

16. The display device of claim 12, wherein
the first layer comprises magnesium fluoride (MgF₂), and
the third layer comprises silicon oxide (SiO₂).

17. The display device of claim 12, wherein the second layer comprises chromium oxide (Cr₂O₃) covalently bonded to silicon (Si).

18. The display device of claim 12, wherein a contact angle of a surface of the window with respect to water is about 95° or more after applying a load of 1 kg to the surface of the window by using an eraser and then reciprocating by a distance of 15 mm at a speed of 40 cycles/min for 6000 times.

19. The display device of claim 12, further comprising:
a pixel defining layer in which a first opening is defined to expose at least a portion of the first electrode.

20. The display device of claim 19, wherein the light-blocking layer defines a second opening overlapping the first opening.

21. The display device of claim 20, wherein at least a portion of the color filter layer is in the second opening.

22. The display device of claim 12, wherein the color filter layer at least partially overlaps the intermediate layer.

23. The display device of claim 12, wherein the filter layer further comprises an overcoat layer disposed on the color filter layer.

24. The display device of claim 12, further comprising:
an encapsulation layer between the light-emitting element and the filter layer; and
an input sensing layer between the encapsulation layer and the filter layer.
